(19) United States
(12) Patent Application Publication
(10) Pub. No.: US 2010/0104772 A1
(43) Pub. Date: Apr. 29, 2010

(54) ELECTRODE AND POWER COUPLING SCHEME FOR UNIFORM PROCESS IN A LARGE-AREA PECVD CHAMBER

(75) Inventors: Jozef Kudela, Sunnyvale, CA (US); Tsutomu (Tom) Tanaka, Santa Clara, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS,INC., Santa Clara, CA (US)

(21) Appl. No.: 12/493,866

(22) Filed: Jun. 29, 2009

Related U.S. Application Data
(60) Provisional application No. 61/108,393, filed on Oct. 24, 2008.

(51) Int. Cl. C23C 16/513; H05H 1/24

(52) U.S. Cl. 427/569; 118/723 MP; 204/164

(57) ABSTRACT

Embodiments discussed herein generally include electrodes having parallel ferrite boundaries that suppress RF currents perpendicular to the ferrite boundary and absorb magnetic field components parallel to the boundary. The ferrites cause the standing wave to stretch outside the ferrites and shrink inside the ferrite. A plurality of power sources are coupled to the electrode. The phase of the VHF current delivered from the power sources may be modulated to move the standing wave that is perpendicular to the ferrites in a direction parallel to the ferrites. Thus, the VHF current on the uncovered electrode area will be a plane wave, quasi-uniform (in a direction perpendicular to the ferrites) propagating in the direction parallel to the ferrites.

### CROSS-REFERENCE TO RELATED APPLICATIONS

This application claims priority to U.S. Provisional Patent Application Ser. No. 61/108,393 (APPM/013758L02), filed Oct. 24, 2008, which is herein incorporated by reference.

### BACKGROUND OF THE INVENTION

1. Field of the Invention

Embodiments of the present invention generally relate to a plasma enhanced chemical vapor deposition (PECVD) apparatus.

2. Description of the Related Art

As demands for larger flat panel displays (FPDs) and solar panels for consumers (and consequently, demands for higher manufacturing cost-efficiency from the FPD and solar panel manufacturers), continues to increase, the size of PECVD chambers that are used for depositing thin films used for FPDs and solar panels increases. The chambers used in the deposition process are typically capacitively driven parallel-plate reactors using RF or VHF fields to ionize and dissociate processing gas between the plate electrodes. Due to finite reactor dimensions and boundary conditions on the electrodes, the excited fields inherently form standing waves. If the size of the electrodes becomes comparable with the excitation wavelengths, electromagnetic effects causing non-uniformities in plasma and deposited films becomes inevitable.

The standing waves and plasma non-uniformities have a strong influence on the thickness and properties of thin films deposited by PECVD reactors or on the process uniformity in plasma processing chambers in general. Non-uniform films may lead to the so-called “mura effects” on FPDs or to low-efficient cells in solar panels. In some cases, plasma non-uniformity may lead to non-functioning devices.

The standing wave effects and related plasma non-uniformities may be overcome to an extent by using shaped electrodes, lens electrodes, cavities behind resistive electrodes, lower frequencies, tuning the processing parameters such as chamber pressure, and combinations thereof. However, when the processing chamber size increases to reflect the demand for larger FPDs and solar panels, simply scaling up the aforementioned countermeasures to the standing wave effect and plasma non-uniformities may not be sufficient.

Therefore, there is a need for a plasma reactor designed to increase plasma uniformity and overcome standing wave effects.

### SUMMARY OF THE INVENTION

Embodiments discussed herein generally include electrodes having parallel ferrite boundaries that suppress RF currents perpendicular to the ferrite boundary and absorb magnetic field components parallel to the boundary. The ferrites cause the standing wave to stretch outside the ferrites and shrink inside the ferrite. A plurality of power sources are coupled to the electrode. The phase of the VHF current delivered from the power sources may be modulated to move the standing wave that is perpendicular to the ferrites in a direction parallel to the ferrites. Thus, the VHF current on the uncovered electrode area will be a plane wave, quasi-uniform (in a direction perpendicular to the ferrites) propagating in the direction parallel to the ferrites.

In one embodiment, an apparatus may include a chamber body having a first wall with a slit valve opening therethrough, an electrode disposed in the chamber body, one or more ferrite pieces extending parallel to the slit valve opening, and a plurality of first VHF power sources coupled to the electrode at a plurality of locations.

In another embodiment, an apparatus may include an electrode, a first power source coupled to the electrode in a first plurality of locations along a first periphery of the electrode, and a second power source separate from the first power source and coupled to the electrode in a second plurality of locations along a second periphery of the electrode parallel to the first periphery. The apparatus may also include one or more first ferrite blocks extending along a third periphery of the electrode perpendicular to the first and second periphery and one or more second ferrite blocks extending along a fourth periphery of the electrode parallel to the third periphery.

In another embodiment, a plasma enhanced chemical vapor deposition apparatus is disclosed. The apparatus may include a processing chamber body having a plurality of sidewalls, at least a first sidewall of the plurality of sidewalls having a slit valve opening therethrough. The apparatus may also include a susceptor disposed within the chamber body and a gas distribution showerhead disposed in the chamber body opposite the susceptor. The apparatus may also include a backing plate disposed in the chamber body adjacent the gas distribution showerhead. The backing plate may have a first side facing the gas distribution showerhead and a second side opposite the first side. The apparatus may also include one or more first ferrite blocks disposed along the second side of the backing plate along a first edge of the second side. The one or more first ferrite blocks may extend substantially parallel to the slit valve opening. The apparatus may also include a first power source coupled to the backing plate on the second side at a second edge perpendicular to the first edge and a second power source separate from the first power source coupled to the backing plate on the second side at a third edge parallel to the second edge.

In another embodiment, a method is disclosed. The method includes applying a first RF or VHF current to an electrode at one or more first locations. The electrode has a generally rectangular shape and one or more ferrite blocks extending along a substantial length of first and second parallel edges. The first RF or VHF current is applied at a first phase, and the first location is located at a third edge of the electrode perpendicular to the first and second edges. The method also includes applying a second RF or VHF current to the electrode at one or more second locations located at a fourth edge of the electrode parallel to the first edge. The second RF or VHF current is applied in a second phase different than the first phase. The phase of the second RF or VHF current relative to the first RF or VHF current can be varied over time.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic cross sectional view of a PECVD apparatus 100 according to one embodiment.

FIG. 1B is a schematic cross sectional view of a FIG. 1A with ferrites present.

FIG. 2A is a schematic top view of an apparatus 200 according to one embodiment.

FIG. 2B is a schematic isometric view of an apparatus 250 according to one embodiment.

FIG. 3 is a graph showing the effects of a ferrite boundary on the standing wave profile.

FIGS. 4A and 4B show the effect of placing magnetic material or ferrites on the edges of the electrode.

FIG. 5 shows the effects of utilizing multiple ferrite boundaries on plasma distribution.

FIG. 6 is a schematic cross sectional view showing various locations for ferrites in a parallel plate apparatus.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments discussed herein generally include electrodes having parallel ferrite boundaries that suppress RF currents perpendicular to the ferrite boundary and absorb magnetic field components parallel to the boundary. The ferrites cause the standing wave to stretch outside the ferrites and shrink inside the ferrite. A plurality of power sources are coupled to the electrode. The phase of the VHF current delivered from the power sources may be modulated to move the standing wave that is perpendicular to the ferrites in a direction parallel to the ferrites. Thus, the VHF current on the uncovered electrode area will be a plane wave, quasi-uniform (in a direction perpendicular to the ferrites) propagating in the direction parallel to the ferrites.

Embodiments disclosed herein will be discussed with reference to a PECVD apparatus available from Applied Materials, Inc., Santa Clara, Calif. It is to be understood that the embodiments discussed herein may have utility in other chambers including those sold by other manufacturers. The embodiments disclosed herein propose a solution for achievement of uniform plasma in the apparatus and/or uniform process conditions in large area RF or VHF capacitive plasma reactors. The solution includes enhancing RF or VHF current uniformity in one direction (for example, the x-axis of a rectangular electrode), and power coupling scheme that moves the non-uniform standing wave field pattern in the other direction (for example, the y-axis of the rectangular electrode) during the deposition process.

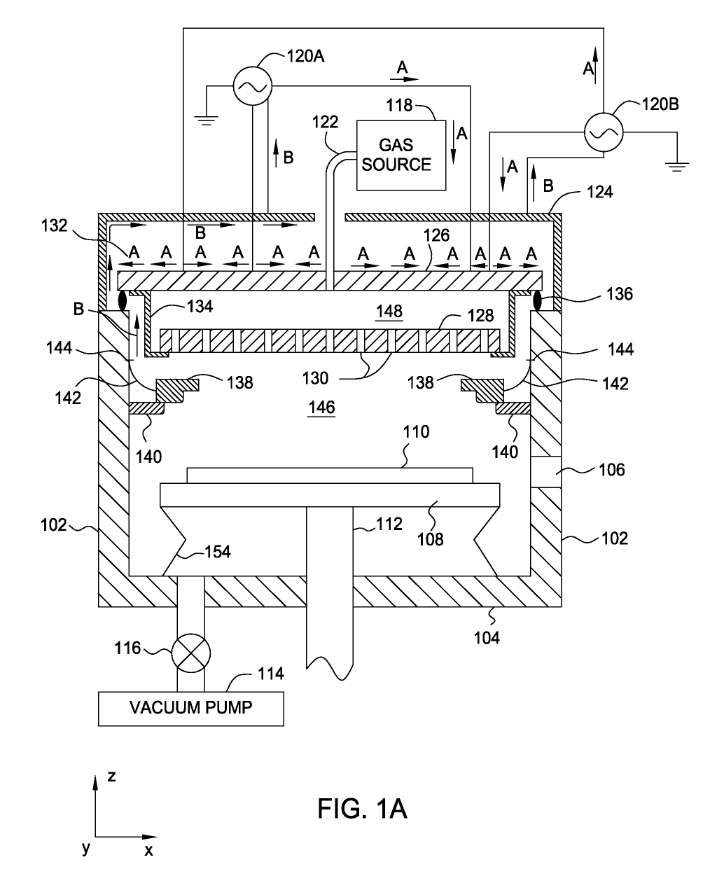

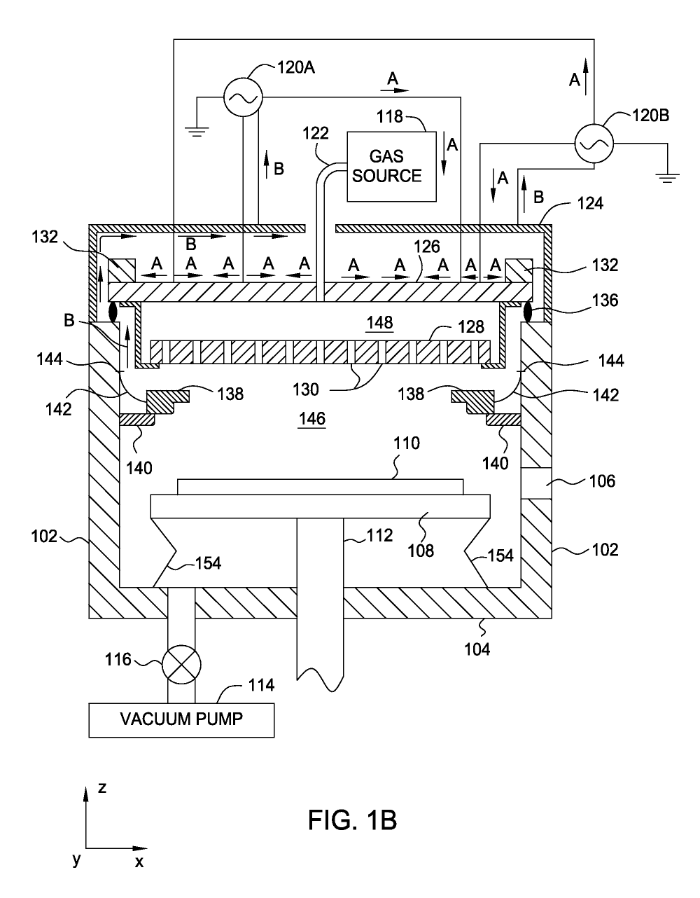

FIG. 1A is a schematic cross sectional view of a PECVD apparatus 100 according to one embodiment. The apparatus 100 comprises a plurality of walls 102 and a bottom 104. In one embodiment, the walls 102 and the bottom 104 may comprise a conductive material. In another embodiment, the walls 102 and bottom 104 may comprise aluminum. Through one or more walls 102, a slit valve opening 106 may be present. The slit valve opening 106 permits a substrate 110 to enter and exit the apparatus 100.

The substrate 110 may be placed on a susceptor 108 when in the apparatus 100. The susceptor 108 may be raised and lowered on a shaft 112. In one embodiment, the shaft 112 and the susceptor 108 may comprise a conductive material. In another embodiment, the shaft 112 and the susceptor 108 may comprise aluminum. The apparatus 100 may be evacuated by a vacuum pump 114. A valve 116 may be coupled between the chamber and the vacuum pump 114 to adjust the vacuum level of the apparatus 100.

Processing gas may be introduced into the apparatus 100 from a gas source 118 through a tube 122 that passes through the chamber lid 124. The tube 122 is coupled to the backing plate 126 to permit the processing gas to pass through the backing plate 126 and enter a plenum 148 between the backing plate 126 and the gas distribution showerhead 128. In one embodiment, the tube 122, the backing plate 126, and the gas distribution showerhead 128 may comprise a conductive material. In another embodiment, the tube 122, backing plate 126, and gas distribution showerhead 128 may comprise aluminum. The processing gas spreads out in the plenum 148 and then passes through gas passages 130 formed through the gas distribution showerhead 128 to the processing area 146. In general, the power may be applied such that ⅛^{th} of the wavelength at the applied frequency is comparable to the chamber diagonal. The chamber diagonal is the distance across a rectangular chamber from one corner to another corner diagonally opposite.

A plurality of power sources 120A, 120B are also coupled to the backing plate 126. In one embodiment, the power sources 120A, 120B comprise RF power sources capable of generating RF currents at a frequency of between about 13.56 MHz and about 100 MHz. In another embodiment, the power sources 120A, 120B comprise VHF power sources capable of generating VHF currents at a frequency of between about 40 MHz and about 60 MHz. In another embodiment, the power sources 120A, 120B comprise VHF power sources capable of generating VHF currents at a frequency of about 27 MHz. In another embodiment, the power sources 120A, 120B are capable of generating VHF currents of about 40 MHz and above. The power sources 120A, 120B may be phase modulated as will be discussed below.

The current from the power sources 120A, 120B flows along the outside surface of the backing plate 126. RF current and VHF current have a ‘skin effect’ in that the current does not penetrate all the way through a conductive body such as the backing plate 126. RF or VHF current travels along the outside surface of a conductive object and penetrates a predetermined distance into the conductive article. The amount that the RF or VHF current penetrates into the conductive article is a function of the frequency of the current and the material properties. The RF or VHF current then travels down a bracket 134 to the front face of the gas distribution showerhead 128. In one embodiment, the bracket 134 may comprise a conductive material. In another embodiment, the bracket 134 may comprise aluminum. The RF or VHF current flows along a path shown by arrows “A”. Thus, the RF current travels along the back surface of the backing plate 126, the side surface of the backing plate 126 the outside surface of the bracket 134, and the bottom surface of the gas distribution showerhead 128.

The RF or VHF current does not travel along the back surface of the gas distribution showerhead 128 that faces the backing plate 126. Additionally, the RF or VHF current does not travel along the front surface of the backing plate 126 that faces the gas distribution showerhead 128. Thus, the gas in the plenum 148 does not see the RF or VHF current and therefore does not ignite into a plasma in the plenum 148.

In the embodiment shown in FIG. 1A, the gas tube 122 is fed into the substantial center of the backing plate 126. It is to be understood that the gas tube 122 could be moved to suit the needs of the user. Moving the gas tube 122 may not have a great affect on the gas distribution because the gas may substantially evenly distribute within the apparatus 100 due to the plenum 148. Hence, the gas flow uniformity into the processing area 146 may be controlled by the plenum 148 as opposed to the location where the gas tube 122 feeds gas into the plenum 148.

For RF or VHF current, on the other hand, the location where the current couples to the backing plate 126 makes a difference. In the embodiment shown in FIG. 1A, two separate power sources 120A, 120B are shown connected to the backing plate 126. Each power source 102A, 120B is coupled to the backing plate 126 at multiple locations. However, it is to be understood that each power source 120A, 120B may be coupled to the backing plate 126 at one location. In one embodiment, the backing plate 126 may have a size of greater than about 60,000 square centimeters.

In the embodiment shown in FIG. 1B, parallel ferrite 132 boundaries on the top of the backing plate 126 are present. The ferrites 132 may suppress RF and/or VHF currents perpendicular to the ferrite 132 boundary and will absorb the magnetic field component parallel to the boundary (i.e., the standing wave pattern in the direction perpendicular to the ferrite 132 boundary will be stretched outside the ferrites 132 and shrunk inside the ferrite 132). The ferrite's 132 relative permeability and geometry may determine what portion of the standing wave profile on the backing plate 126 will move into the ferrites 132. For the areas of the backing plate 126 not covered by ferrites 132, a plane wave with fields that are quasi-uniform in one direction (for example, the x direction) and propogating in the other, perpendicular direction (for example, the y-direction). The non-uniformity in the wave propagation direction will still exist, but may be resolved by moving the standing wave pattern in the perpendicular direction by using the multiple power sources 120A, 120B with phase and/or amplitude control and/or by moving the substrate. Further control and/or improvement of the uniformity may be achieved by using the multiple feeds with uneven power distribution and/or using multiple ferrite 132 boundaries on the backing plate 126. The design and power coupling may enhance the RF and/or VHF drive in the parallel direction (and/or suppress the perpendicular direction). Therefore, any uniformity issues caused by the slit valve opening 106 may be substantially reduced by placing ferrites 132 parallel to the slit valve opening 106.

For the embodiment shown in FIG. 1B, the ferrites 132 extend along an edge of the backing plate 126 parallel to the slit valve opening 106. The edges of the backing plate 126 extending perpendicular to the slit valve opening 106 do not have ferrites 132 extending thereon. However, the ends of the ferrites 132 do cover a short distance of the edge perpendicular to the slit valve opening 106. It is to be understood that the ferrites 132 may be placed in other orientations. For example, the ferrites 132 may extend along the edge of the backing plate 126 perpendicular to the slit valve opening 106 instead of the edges parallel to the slit valve opening 106. Additionally, if desired, the ferrites 132 may be present on all edges. However, if ferrites 132 are present on all edges, it may be necessary to have some gaps therebetween to permit the RF or VHF current to travel down to the gas distribution showerhead 128.

In the apparatus 100, there are four walls 102. Of those four walls 102, three of the walls 102 are substantially identical and look substantially identical to the RF or VHF current (in absence of the ferrites 132) when it travels thereon returning to the power sources 120A, 120B as shown by arrows “B”. The fourth wall 102, however, is different than the other walls 102 and looks different to the RF or VHF current as it returns to the power sources 120A, 120B. The fourth wall 102 has the slit valve opening 106 therethrough. The RF or VHF current travels a different path along the wall 102 having the slit valve opening 106. The RF or VHF current actually travels along the slit valve opening 106. Thus, the RF or VHF current traveling along the wall 102 having the slit valve opening 106 has a longer inductive path to return to the power sources 120A, 120B as compared to the three other walls 102.

As the RF or VHF current travels back to the power sources 120A, 120B, the potential of the RF or VHF current decreases. Hence, the potential difference between the RF or VHF current flowing along the three substantially identical walls 102 back to the power sources 120A, 120B and the gas distribution showerhead 128 is different than the difference between the RF or VHF current flowing along the wall 102 having the slit valve opening 106 and the gas distribution showerhead 128, in absence of the ferrites 132. The slit valve opening 106 is a part of the RF return path and therefore leads to an asymmetry along the chamber walls. The asymmetric RF return path shifts the standing wave and thus, unevenly distributes the plasma within the apparatus 100. With an uneven plasma distribution, a uniform deposition of material onto the substrate 110 may not occur.

The ferrites 132 may be used to substantially reduce the effect of the slit valve opening 106. Ferrites 132 may be used to lengthen the RF return path along the wall opposite to the slit valve (i.e., the ferrites 132 would be placed, for example, above the electrode or backing plate opposite to the slit valve opening 106). The RF return path may be lengthened by using thicker ferrites 132 or stronger ferrites 132 opposite the slit valve opening 106. In the embodiment shown in FIG. 1B, the ferrites 132 extend parallel to the slit valve opening 106. The ferrites 132 suppress the RF or VHF current flowing along the edge of the backing plate 126 having ferrites 132 thereon and hence, the side of the gas distribution showerhead 128. The RF or VHF current, when returning to the sources 120A, 120B, seeks to take the shortest path possible. Hence, when returning to the source 120A, 120B, the RF or VHF current will flow along the walls 102 perpendicular to the slit valve opening 106 (and hence, the ferrites 132) because the walls 102 perpendicular to the slit valve opening 106 (and hence, the ferrites 132) offer the shortest path to return to the sources 120A, 120B. Some RF or VHF current may, however, return to the sources 120A, 120B along the walls 102 parallel to the slit valve opening 106 (and hence, the ferrites 132), but the amount of RF or VHF current that flows along the walls 102 parallel to the slit valve opening 106 (and hence, the ferrites 132) is insignificant relative to the RF or VHF current returning to the sources 120A, 120B along the walls 102 perpendicular to the slit valve opening 106 (and hence, the ferrites 132). Therefore, because little or no RF or VHF current returns to the sources 120A, 120B along the walls 102 parallel to the slit valve opening 106 (and hence, the ferrites 132), the negative effect of the slit valve opening 106 may be substantially reduced, or in some cases, eliminated.

When the susceptor 108 raises the substrate 110 for processing, the susceptor 108 encounters a shadow frame 138 while moving to the processing position. The shadow frame 138 may prevent arcing between the susceptor 108 and the substrate coating top. The shadow frame 138 may rest on a ledge 140 prior to being displaced by the susceptor 108. The shadow frame 138 may also be a part of the RF or VHF return path. One or more straps 142 may be coupled to both the shadow frame 138 as well as the inside surface of the walls 102. The straps 142 may be coupled to the inside surface of the walls 102 with one or more fastening mechanisms 144. In one embodiment, the fastening mechanism 144 may comprise a screw. The RF or VHF current travels along the susceptor 108, the straps 154, the inside surface of the walls 102, the lid 124, and back to the power sources 120A, 120B as shown by arrows “B” to complete the RF or VHF circuit.

By suppressing RF or VHF current with the ferrites spanning a length of the backing plate 126 parallel to the slit valve opening 106, the RF or VHF current in the direction of the slit valve opening (and opposite thereto) is controlled. However, because no ferrites 132 are perpendicular to the slit valve opening 106 (or vice versa), the RF or VHF current that runs parallel to the slit valve opening 106 (or vice versa) is not controlled. Thus, the ferrites 132 remove one degree of uncertainty to control of the RF or VHF current. The control of the RF or VHF current in the direction parallel to the slit valve opening 106 aids in plasma uniformity and thus, deposition uniformity.

To deposit material on the substrate 110, processing gas is introduced from the gas source 118 through the backing plate 126 and into the plenum 148. Then, the processing gas passes through the gas passages 130 formed in the gas distribution showerhead 128 and into the processing area 146. The RF or VHF current flows along the tube 122, the back surface of the backing plate 126, the bracket 134, and the front surface of the showerhead 128. The induced RF or VHF fields then ignite the processing gas into a plasma which deposits material onto the substrate 110. The RF or VHF current propagates through the plasma to the substrate 110 and along the shadow frame 138, the straps 142, the walls 102, and the lid 124 back to the power source 120A, 120B. In one embodiment, the straps 142 may be present along the walls 102 perpendicular to the ferrites 132 but not present on the walls parallel to the ferrites 132. In another embodiment, the straps 142 may be coupled to all walls 102.

It is to be understood that while the ferrites 132 have been discussed as being located behind the backing plate 126 on the atmosphere side of the chamber, the ferrites 132 may be placed in other locations as well. When the ferrites 132 are placed on the front surface of the gas distribution showerhead 128, the ferrites 132 may be enclosed in a cover such as a dielectric or ceramic cover to prevent the ferrites 132 from sputtering. Other potential locations for the ferrites 132 include under the susceptor 108, adjacent the backing plate 126, and adjacent the chamber walls 102 between the substrate 110 and the gas distribution showerhead 128. Additionally, while ferrites 132 have been described, it is to be understood that any ferromagnetic material, conducting or non-conducting, non-oriented, or ferromagnetic material, or oriented material such as magnets may be used.

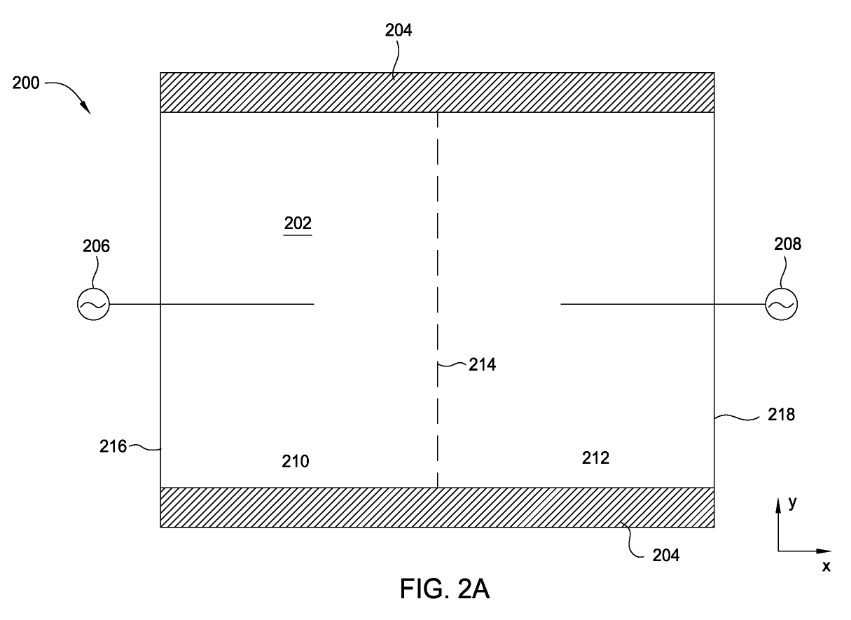

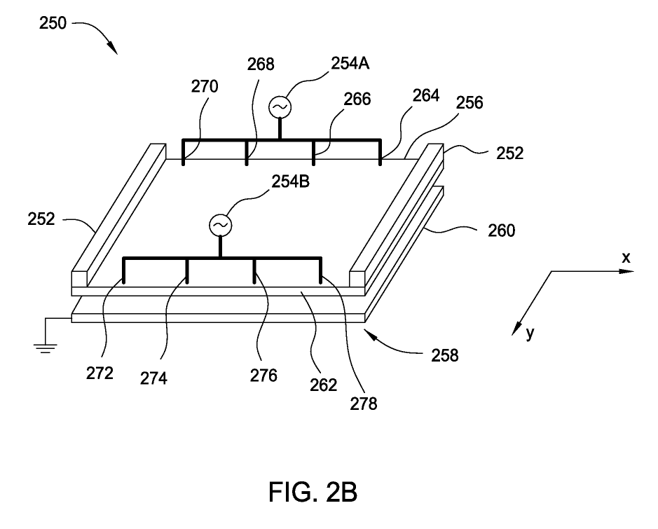

FIG. 2A is a schematic top view of an apparatus 200 according to one embodiment. The apparatus includes an electrode 202 having ferrites 204 that span the length of two parallel sides of the electrode 202. The electrode 202 may be hypothetically divided in half at the center line 214 and separate power sources 206, 208 may be applied to each half 210, 212 of the electrode 202. The power sources 206, 208 may be coupled to the halves 210, 212 at locations spaced from the edges 216, 218 of the halves 210, 212. In one embodiment, the power sources 206, 208 may be coupled to the halves 210, 212 at the edges 216, 218. The RF or VHF current may be applied to the halves 210, 212 from the power sources 206, 208 such that the standing wave moves across the underside of the electrode 202. The ferrites 204 prevent or reduce the flow of the RF or VHF current in the “Y” direction, but permit the RF or VHF current to travel in the “X” direction. By modulating the power applied to the halves 210, 212, together with the ferrites 204 suppressing the RF or VHF current in the “Y” direction, the standing wave may be moved across the bottom face of the electrode 202. Alternatively, the substrate may be moved.

FIG. 2B is a schematic isometric view of an apparatus 250 according to one embodiment. As shown in FIG. 2B, ferrites 252 span a length of an electrode 256 along an edge 260. The electrode 256 is positioned opposite the susceptor 258. A plurality of power sources 254A, 254B are shown coupled to the electrode 256, each coupled at a plurality of contact points 264, 266, 268, 270, 272, 274, 276, 278. One power source 254B is coupled to an edge 262 of the electrode 256. The other power source 254A is coupled at a plurality of contact points 264, 266, 268, 270 at an edge opposite to the edge 262. The power sources 254A, 254B may be driven out of phase with each including operating in a push-pull arrangement. For example, power source 254A will be driven in a first phase and the other power source 254B will be driven in a phase opposite to the first phase. Therefore, each power source 254B will act as the return path for the other power source 254A and vice versa. In one embodiment, the power sources 254A, 254B may operate in the same phase. In another embodiment, the power sources 254A, 254B may operate close to out of phase with each other. It is to be understood that while the power sources 254A, 254B have been shown coupled at the edges, the power sources 254A, 254B may be coupled at other locations as well that are spaced from the edges.

A non-uniform standing wave profile in the y-direction can be moved by means of time-varying asymmetric (in phase or amplitude or both) drive (i.e., two feeds on electrode sides (non-ferrite sides) or a feed on one side and variable capacitor on the other side. Thus, a time-averaged uniform field plasma may be formed. The profiles can be controlled/improved by using multiple contact points 264, 266, 268, 270, 272, 274, 276, 278 on each side with uneven power distribution, or by multiple ferrite boundaries. Anisotropy in the excited RF/VHF fields/currents on the electrodes may also help with the slit valve effect issue. The currents are driven in parallel to the slit valve (ferrite boundaries parallel with the slit valve). Additionally, due to multiple contact points 264, 266, 268, 270, 272, 274, 276, 278 the current delivered to the different contact points 264, 266, 268, 260, 262, 264, 266, 268 may be different.

The boundary condition is affected by the magnetic material. By shortening the magnetic component parallel to the edge, a high magnetic permeability material will force the magnetic field, and thus the wave front, to be perpendicular to the edges and help form plane waves. In other words, a high magnetic permeability may increase the electrical length to the side and effectively extend the electrode.

It is to be understood that while the ferrites 252 have been shown as a single piece spanning the entire length of the electrode 256, the ferrites 252 may comprise multiple pieces. The multiple pieces may each span the entire length or the multiple pieces may be coupled together to collectively span the entire length. Additionally, if desired, the multiple ferrite 252 pieces may be spaced apart. Additionally, the contact points 264, 266, 268, 270, 272, 274, 276, 278 may be moved laterally. The electrode 256 may be a scooped gas distribution showerhead having a concave bottom surface facing the susceptor 258. In one embodiment, the electrode 256 may comprise a gas distribution showerhead having a substantially planar surface facing the susceptor 258. The ferrites 252 may be spaced from the electrode 206.

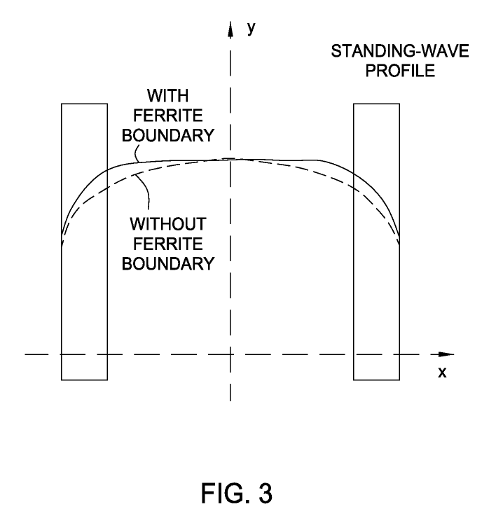

FIG. 3 is a graph showing the effects of a ferrite boundary on the standing wave profile. The ferrite boundaries on the electrode edges move part of the standing wave profile into the ferrites (i.e., the standing wave pattern on the uncovered electrode area will be spread and thus, more uniform) as shown in FIG. 3 which compares the standing wave profile for an electrode with ferrites to an electrode without ferrites. As shown in FIG. 3, the standing wave profile in the situation where ferrites are present results in a flatter profile as compared to the situation where no ferrites are present. By flattening out the standing wave profile, the plasma uniformity in the “X” direction may be substantially uniform. The RF or VHF currents may be enhanced in the direction parallel to the ferrite boundary and suppressed in the direction perpendicular to the ferrite boundary. A plane wave like propagation between the ferrite boundaries (i.e., magnetic field components parallel to the ferrite boundaries move into the ferrites) is created.

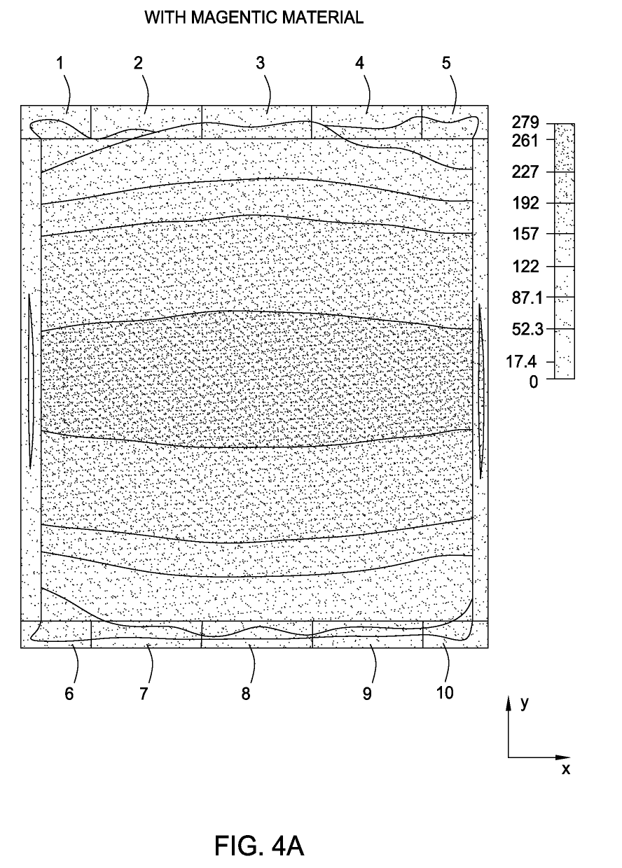

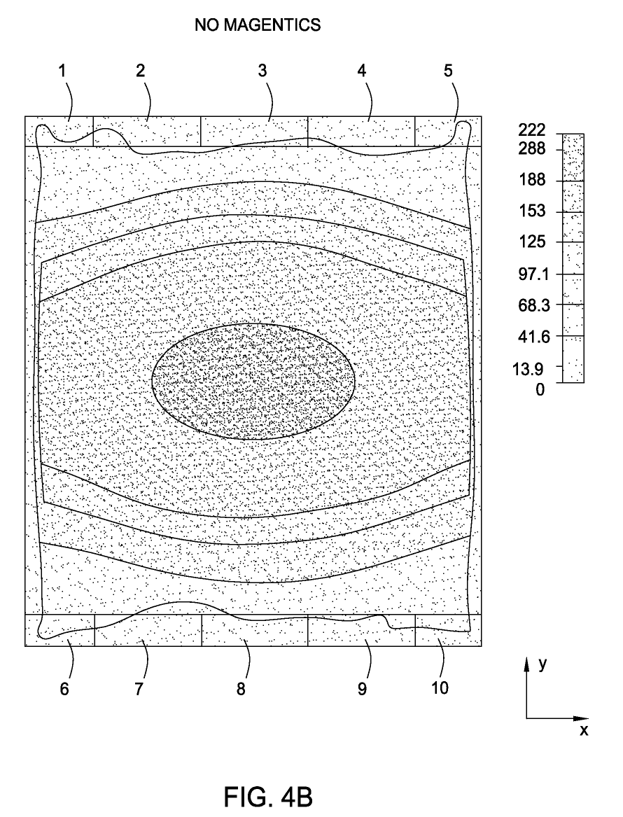

FIGS. 4A and 4B show the effect of placing magnetic material or ferrites on the edges of the electrode. In both FIGS. 4A and 4B, the electrode is powered at opposite ends with a VHF frequency of 40 MHz. The VHF current is applied at five separate locations with the same phase. As shown in FIG. 4A, when magnetic material or ferrites span the edge of sides perpendicular to the sides having the VHF power coupled thereto, the plasma generated is substantially uniform in the “X” direction. By phase modulating the VHF current applied to the electrode, the location where the plasma is most intense may be scanned the length of the electrode such that a substantially uniform plasma is present in not only the “X” direction but also the “Y” direction. By comparison, FIG. 4B shows the same electrode and conditions, except that the magnetics or ferrites have been removed. As can be seen, the plasma is most intense in the middle and not uniform in either the “X” or “Y” direction. Even though the VHF current is launched from two opposite sides, the combined plasma field has a domed shaped pattern with the greatest concentration near the substantial center of the electrode. When the two power sources are phased, the dome moves from end to end, but not side to side. Thus, there is a plasma nonuniformity.

It is possible to deliver the VHF current from all sides and phasing in each direction, but such complexity is not necessary when using a ferrite system. The complexity is due to the plane waves that are launched from the power sources which make a linear wave front and makes the problem one dimension. Deflection from edges makes plane waves difficult and results in the domed wave front.

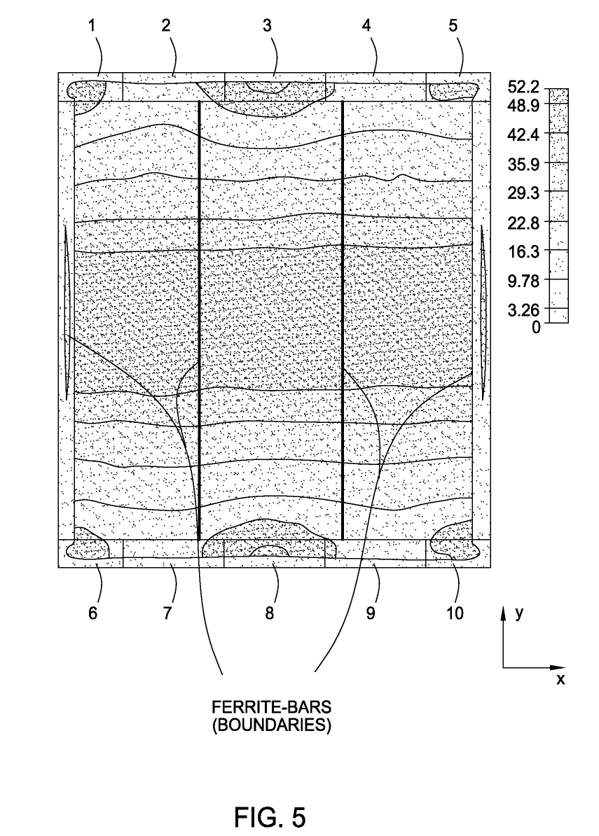

FIG. 5 shows the effects of utilizing multiple ferrite boundaries on plasma distribution. In FIG. 5, a 60 MHz VHF current was delivered to the electrode. The power was evenly distributed along the two opposite edges of the electrode. Ferrites spanned the length along the edges perpendicular to the edges where the power was delivered. Additionally, ferrites spanned the length along in the middle of the electrode to create additional ferrite boundaries. As shown in FIG. 5, the ferrite boundaries create three separate zones. Each zone has substantially evenly distributed plasma in the “X” direction which can be moved in the “Y” direction by phase modulating the VHF current delivered to the electrode.

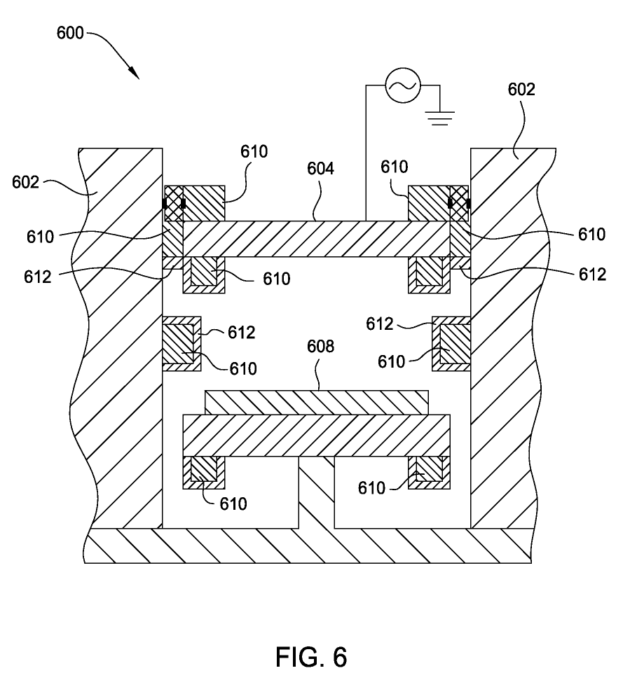

FIG. 6 is a simplified schematic cross sectional view illustrating various locations in which ferrites 610 can be positioned in relation to a processing area 646 within a parallel plate apparatus 600. The ferrites 610 may be placed on the back surface of the electrode 604 (i.e., backing plate/showerhead illustrated in FIG. 1B), on the surface of the electrode 604 facing the substrate 608, under the susceptor 606, or even on the walls 602. When the ferrites 610 are behind the electrode 604, the ferrites 610 may be in an atmospheric environment. However, when the ferrites 610 are positioned under the susceptor 606, on the electrode 604 facing the substrate 608, or on the walls 602, they may need to be covered by a cover 612 to isolate them from the vacuum environment. The cover 612 can be used to prevent the ferrites 610 from contaminating the processing environment due to attack caused by the radicals in the plasma, oxidation, corrosion, or by sputtering caused energetic species in the plasma. In one embodiment, the cover 612 may comprise an insulating material. The benefits to having the ferrites 610 on the atmospheric side of the electrode 604 include easy access to the ferrites 610, not exposed to reactive gas or high temperatures, and the need for less material because no cover is necessary. Additionally, the ferrites 610 may be between a backing plate and a showerhead in a PECVD system. The ferrites 610 may even be spaced from the electrode 604 for thermal purposes.

By utilizing ferrites strategically placed in a parallel plate reactor, better control of the RF or VHF current may occur. The ferrites may compensate for the standing wave effect and increase plasma uniformity. Due to an increased plasma uniformity, a more uniform and repeatable deposition may occur in the parallel plate reactor.

While the foregoing is directed to embodiments of the present invention, other and further embodiments of the invention may be devised without departing from the basic scope thereof, and the scope thereof is determined by the claims that follow.

1. An apparatus, comprising:
a chamber body having a first wall with a slit valve opening therethrough;
an electrode disposed in the chamber body;
one or more ferrite pieces extending parallel to the slit valve opening; and
a plurality of first VHF power sources coupled to the electrode at a plurality of locations.

2. The apparatus of claim 1, wherein a first VHF power source is coupled along an edge of the electrode perpendicular to the slit vale opening.

3. The apparatus of claim 2, further comprising a second power source separate from the first power source and coupled to the electrode at a plurality of locations opposite the first power source.

4. The apparatus of claim 1, wherein the first power source is a VHF power source capable of operating at 40 MHz or more.

5. The apparatus of claim 1, further comprising one or more second ferrite pieces extending parallel to the slit valve opening and separate from the one or more first ferrite pieces.

6. The apparatus of claim 5, wherein the one or more second ferrite pieces and the one or more first ferrite pieces are disposed in substantially the same plane on opposite sides of the electrode.

7. The apparatus of claim 1, wherein the electrode is a gas distribution showerhead.

8. The apparatus of claim 1, wherein the apparatus is a plasma enhanced chemical vapor deposition apparatus.

9. An apparatus, comprising:
an electrode;
a first power source coupled to the electrode in a first plurality of locations along a first periphery of the electrode;
a second power source separate from the first power source and coupled to the electrode in a second plurality of locations along a second periphery of the electrode parallel to the first periphery;
one or more first ferrite blocks extending along a third periphery of the electrode perpendicular to the first and second periphery; and
one or more second ferrite blocks extending along a fourth periphery of the electrode parallel to the third periphery.

10. The apparatus of claim 9, wherein the electrode is a gas distribution showerhead.

11. The apparatus of claim 9, wherein the apparatus is a plasma enhanced chemical vapor deposition apparatus.

12. A plasma enhanced chemical vapor deposition apparatus, comprising:
a processing chamber body having a plurality of sidewalls, at least a first sidewall of the plurality of sidewalls having a slit valve opening therethrough;
a susceptor disposed within the chamber body;
a gas distribution showerhead disposed in the chamber body opposite the susceptor;
a backing plate disposed in the chamber body adjacent the gas distribution showerhead, the backing plate having a first side facing the gas distribution showerhead and a second side opposite the first side;
one or more first ferrite blocks disposed along the second side of the backing plate along a first edge of the second side, the one or more first ferrite blocks extend substantially parallel to the slit valve opening;
a first power source coupled to the backing plate on the second side at a second edge perpendicular to the first edge; and
a second power source separate from the first power source coupled to the backing plate on the second side at a third edge parallel to the second edge.

13. The apparatus of claim 12, wherein the first edge is adjacent the first sidewall.

14. The apparatus of claim 13, further comprising one or more second ferrite blocks separate from the one or more first ferrite blocks, the one or more second ferrite blocks disposed along the second side of the backing plate along a fourth edge substantially parallel to the first edge.

15. The apparatus of claim 12, wherein the first power source is coupled to the second edge at a plurality of locations.

16. The apparatus of claim 15, wherein the second power source is coupled to the fourth edge at a plurality of locations.

17. The apparatus of claim 16, wherein the first power source and the second power source are VHF power sources capable of operating at frequencies of about 40 MHz or greater.

18. A method, comprising:
applying a first RF or VHF current to an electrode at one or more first locations, the electrode having a generally rectangular shape and one or more ferrite blocks extending along a substantial length of first and second parallel edges, the first RF or VHF current applied at a first phase, and the first location located at a third edge of the electrode perpendicular to the first and second edges; and
applying a second RF or VHF current to the electrode at one or more second locations located at a fourth edge of the electrode parallel to the first edge, the second RF or VHF current applied in a second phase opposite to the first phase.

19. The method of claim 18, wherein the first RF or VHF current is applied at a plurality of first locations.

20. The method of claim 19, wherein the second RF or VHF current is applied at a plurality of second locations.

21. The method of claim 18, further comprising modulating the first RF or VHF current and the second RF or VHF current to move a standing wave generated by the first and second RF or VHF currents across the electrode.

22. The method of claim 18, wherein the method is a plasma enhanced chemical vapor deposition method.
